(19) United States
(12) Patent Application Publication
(10) Pub. No.: US 2011/0108099 A1
(43) Pub. Date: May 12, 2011

(54) METHOD OF FORMING TRANSPARENT ZINC OXIDE LAYERS FOR HIGH EFFICIENCY PHOTOVOLTAIC CELLS

(75) Inventors: Mustafa Pinarbasi, Morgan Hill, CA (US); James Freitag, Sunnyvale, CA (US)

(73) Assignee: SoloPower, Inc., San Jose, CA (US)

(21) Appl. No.: 12/616,578

(22) Filed: Nov. 11, 2009

(51) Int. Cl. H01L 31/00; H01L 21/283

(52) U.S. Cl. 136/255; 438/609; 257/E21.159

(57) ABSTRACT

A solar cell including a high electrical resistivity transparent layer formed on a CdS buffer layer is provided. The high electrical resistivity transparent layer includes an intrinsic oxide film formed on the buffer layer and an intermediate oxide film formed on the intrinsic oxide film. The intrinsic oxide film includes undoped zinc oxide and has a thickness range of 10 to 40 nm. The intermediate oxide film includes semi-intrinsic zinc oxide doped with aluminum and has a thickness range of 50-150 nm. The intermediate oxide film has an aluminum concentration of less than 1000 ppm.

### BACKGROUND OF THE INVENTION

1. Field of the Invention

The present invention generally relates to methods and apparatus for fabricating thin film solar cells employing CIGS absorber layers. More specifically the present invention describes a method for manufacturing transparent layers including zinc oxide.

2. Description of the Related Art

Solar cells are photovoltaic (PV) devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ(S_{y}Se_{1-y})ₖ, where 0≦x≦1, 0≦y≦1 and k is approximately 2, have already been employed in solar cell structures that yielded conversion efficiencies approaching 20%. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications. It should be noted that although the chemical formula for the absorbers is often written as Cu(In,Ga)(S,Se)₂, a more accurate formula for the compound is Cu(In,Ga)(S,Se)ₖ, where k is typically close to 2 but may not be exactly 2. For simplicity we will, occasionally, continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The structure of a conventional Group IBIIIAVIA compound photovoltaic cell such as a Cu(In,Ga,Al)(S,Se,Te)₂ thin film solar cell is shown in FIG. 1A. The device 10 is fabricated on a substrate 11, such as a sheet of glass, a sheet of metal (such as aluminum or stainless steel), an insulating foil or web, or a conductive foil or web. The absorber film 12, which includes a material in the family of Cu(In,Ga,Al)(S,Se,Te)₂, is grown over a conductive layer 13, which is previously deposited on the substrate 11 and which acts as the electrical contact to the device. The structure including the substrate 11 and the conductive layer 13 or the contact layer, is often called a base 16. Various conductive layers comprising Mo, Ta, W, Ti, and nitrides of these materials etc. have been used in the solar cell structure of FIG. 1A. If the substrate itself is a properly selected conductive material, it is possible not to use a conductive layer 13, since the substrate 11 may then be used as the ohmic contact to the device. After the absorber film 12 is grown, a transparent layer 14 is formed on the absorber film 12. Radiation 15 enters the device through the transparent layer 14. Metallic grids (not shown) may also be deposited over the transparent layer 14 to reduce the effective series resistance of the device. It should be noted that the structure of FIG. 1A may also be inverted if substrate is transparent so that light enters the device from the substrate side of the solar cell.

As shown in FIG. 2B in a detail cross-sectional view of the top portion of the solar cell 10, the transparent layer 14 often includes a stack structure comprising a first transparent layer 16 or buffer layer and a second transparent layer 17. Traditionally, the buffer layer has been called the window layer, since it lets the light pass down to the absorber film. The buffer layer 16 is typically a CdS film. However, various buffer layers with various chemical compositions have been evaluated in solar cell structures. CdS, ZnS, Zn—S—OH, Zn—S—O—OH, ZnO, Zn—Mg—O, Cd—Zn—S, ZnSe, In—Se, In—Ga—Se, In—S, In—Ga—S, In—O—OH, In—S—O, In—S—OH, etc. are some of the buffer layer materials that have been reported in the literature. Buffer layers for Group IBIIIAVIA devices such as CIGS(S) solar cells are typically 5-200 nm thick and may be deposited by various techniques such as evaporation, sputtering, atomic layer deposition (ALD), electrodeposition and chemical bath deposition (CBD), and the like.

The second transparent layer 17 often includes a stack structure of a high resistance film 17A and a conductive film 17B formed on the buffer layer 16. The high resistivity film 17A is an undoped-ZnO film or intrinsic ZnO film (i-ZnO), and the conductive film can be a doped-ZnO, such as Al doped ZnO, or In—Sn—O (ITO), or the like. The conductive film needs to be both highly conductive and as transparent as possible to solar radiation. In manufacturing the cell, the buffer film 16 such as CdS is first deposited on the Group IBIIIAVIA absorber film 12 to form an active junction. The high resistance film 17A including undoped ZnO is deposited on the buffer layer 16 including CdS. The conductive film 17B such as Al doped ZnO is deposited over to provide the needed lateral conductivity. Such doped ZnO layers typically include a conductor (Al) concentration of 2-3% by weight. A high resistivity undoped ZnO film formed between the buffer layer 16 and the conductive film 17B is essential for manufacturing high efficiency photovoltaic cells.

The undoped ZnO film covers the deposition flaws in the buffer layer and increases the efficiency and life time of the solar cells. Further, the undoped ZnO film acts as a diffusion barrier between the CdS layer and the heavily doped conductive film 17B. In fact, to cover the flaws in the buffer layer and to act as a barrier layer against the dopant diffusion from the conductive layer, the undoped layer needs to be about 50 nm thick. However, due to their high electrical resistivity, the undoped ZnO films must be deposited by RF sputtering techniques using intrinsic ZnO targets. Furthermore, RF sputtering of intrinsic ZnO is a slow and costly process allowing limited deposition rates when compared to the DC sputtering techniques using conductive targets. Specifically, for a given material, the deposition rate using DC sputtering can be up to 3-4 times faster than RF sputtering. Therefore, depositing 50 nm thick intrinsic ZnO by RF sputtering significantly reduces production efficiency. On the other hand, reducing the thickness of the intrinsic ZnO layer below 50 nm will seriously weaken its barrier function and significantly degrade the quality of the solar cells.

In another approach, a highly resistive ZnO layer is deposited by DC sputtering from a doped ZnO target in a reactive oxygen atmosphere. This method provides a ZnO layer with high resistivity and high deposition throughput; however, the dopant in this layer is susceptible to diffusion into the CdS layer. Further, compared to RF-sputtering, low pressure DC sputtering is a higher energy process that can cause more interfacial mixing between ZnO and CdS leading to performance degradation.

From the foregoing, there is a need for low cost high efficiency processes to deposit high quality undoped ZnO films to achieve better CdS—ZnO interface that can improve the overall solar cell performance.

### SUMMARY OF THE INVENTION

The present invention is related to methods and apparatus for fabricating thin film solar cells employing an intermediate layer interposed between an undoped zinc oxide layer which is formed over a CdS buffer layer and a doped zinc oxide layer including a conductive dopant material such as aluminum.

### BRIEF DESCRIPTION OF THE DRAWINGS

FIG. 1A is a schematic illustration of a solar cell employing a Group IBIIIAVIA absorber layer;

FIG. 1B is a schematic view of a transparent layer of the solar cell shown FIG. 1A;

FIG. 2A is schematic view of a partially constructed solar cell having a CdS buffer layer at the top;

FIGS. 2B-2C are schematic views showing the steps of building an high resistivity transparent layer of the present invention formed on the buffer layer shown in FIG. 2A;

FIG. 2D is schematic view of a transparent conductive layer formed on the high resistivity transparent layer shown in FIG. 2C; and

FIG. 3 is a schematic view of a solar cell including the high resistivity transparent layer of the present invention.

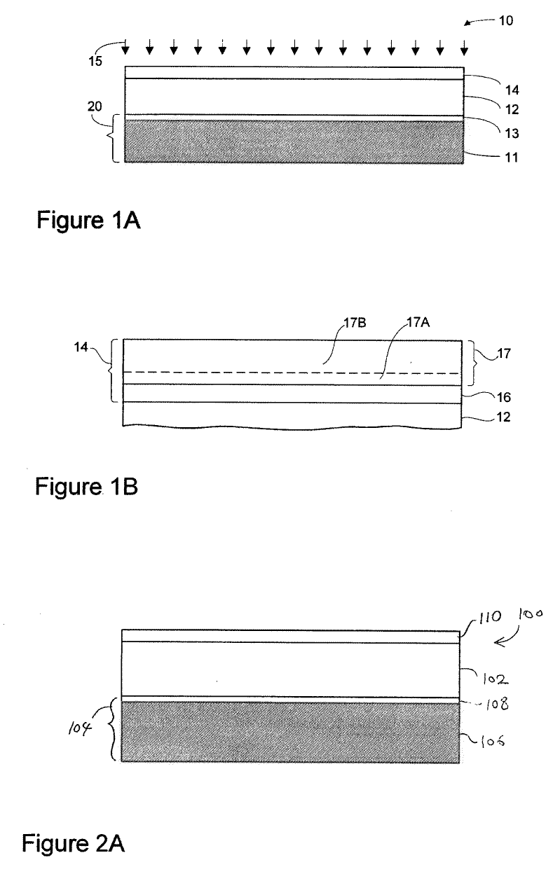

### DETAILED DESCRIPTION OF THE INVENTION

In one embodiment of the present invention, a transparent layer interposed between the buffer layer and the transparent conductive oxide (TCO) layer. The high electrical resistivity transparent oxide layer may be a bilayer including an RF sputtered undoped zinc oxide film deposited on the buffer layer and a pulsed DC or DC sputtered semi-intrinsic zinc oxide film deposited on the undoped zinc oxide film. The semi-intrinsic zinc oxide layer includes a very minimal or trace amount of conductive dopants. A conductive dopant concentration of the semi-intrinsic zinc oxide film is less than 150 ppm. The thickness of the semi-intrinsic zinc oxide film is sufficient to effectively block conductive atom diffusion towards the buffer layer, especially, during the subsequent deposition step of transparent conductive oxide, which typically contains a high concentration of conductive atom dopants, up to 2-3%.

In one embodiment, to form the transparent layer of the present invention, first a very thin, for example 10-20 nm thick, undoped zinc oxide film is RF sputter deposited on the buffer layer using undoped ZnO targets. Since the undoped zinc oxide layer is very thin, the RF sputtering process is performed in short time with high efficiency. In the following step, the rest of the transparent layer, i.e, the semi-intrinsic zinc oxide layer, can be deposited using a second ZnO target that is less pure i.e. containing ppm level aluminum oxide (preferably less than 150 ppm) allowing higher deposition rate processes such as pulsed-DC or DC sputtering. This feature of the invention also sets it apart from the prior art processes since most conventional conductive ZnO targets are doped with up to 2.0 to 3.0% Al₂O₃, by weight. In the present invention however, the ZnO target for the semi-intrinsic zinc oxide layer is doped with as little as 100 ppm Al₂O₃. The low amount of alumina in the semi-intrinsic ZnO layer of the transparent layer coupled with the undoped pure ZnO deposited by RF sputtering in the initial step minimize diffusion of aluminum into the buffer or CIGS layers and eliminates the consequential loss of efficiency. In the first and second steps of the deposition, a small partial pressure of oxygen, approximately 2%, can be added to enhance the resistivity and transmittance of the transparent layer. Once the transparent ZnO layer is formed using this two-step method, the transparent conductive oxide layer of the top contact can be deposited. This transparent conductive oxide layer can be composed of, among other materials, doped ZnO (Al doped) or ITO.

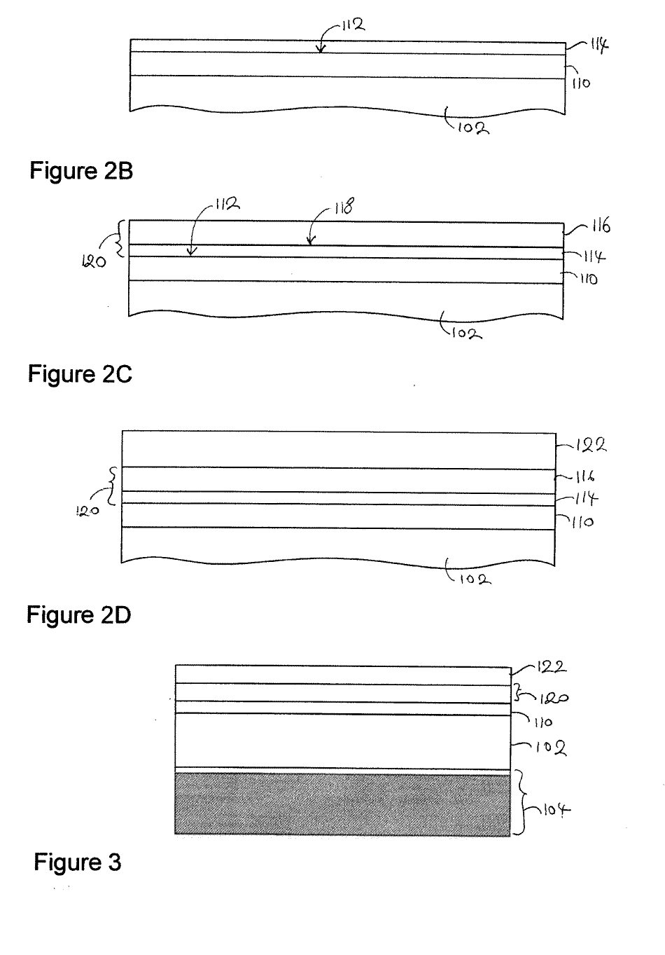

An embodiment of the process of the present invention will be exemplified below using FIGS. 2A-3. FIG. 2A shows a workpiece 100 including a partially constructed solar cell structure having an absorber layer 102 formed over a base 104. The absorber layer 102 may be a Group IBIIIAVIA compound layer. The base includes a substrate 106 and a contact layer 108 or back contact, such as a layer of molybdenum (Mo), formed over the substrate 106. The substrate may be a flexible substrate which may be made of a stainless steel or aluminum foil, or the like. A buffer layer 110, for example a CdS layer, is formed over the absorber layer 102. The workpiece 100 may be a continuous workpiece including a plurality of absorber layer/buffer layer stacks formed over a common base. Such continuous workpiece can be used in a roll to roll process to perform the following process of the present invention. Accordingly, a transparent layer of the present invention and the subsequent layers may be formed over a plurality of absorber layer/buffer layer stacks as the continuous workpiece is advanced through a deposition station and other process stations.

FIG. 2B shows a top portion of the workpiece after a first transparent film 114 is deposited on a surface 112 of the buffer layer 110 to form the first section of a transparent layer 120 of the present invention (FIG. 2C). The first transparent film 114 is a high electrical resistivity film comprising pure ZnO or undoped ZnO. The first transparent film is preferably RF sputter deposited from an undoped ZnO target. A preferred thickness range for the first transparent film 114 may be in the range of 10-40 nm, preferably 20 nm, which may be formed at a deposition rate of less than 2 nm/sec. The sputtering process may be performed in a sputter deposition chamber.

As shown in FIG. 2C, once the first transparent film 114 is deposited, a second transparent film 116 is deposited on a surface 118 of the first transparent film to form the transparent layer 120 or stack of the present invention. The second transparent film 116 is preferably a semi-intrinsic ZnO layer including very small amount of a conductive dopant such as Al. The second transparent film 116 includes 50 to 5000 ppm of Al or preferably 150 ppm of Al. The second transparent film 116 is sputter deposited from a semi-intrinsic ZnO target including aluminum oxide (Al₂O₃) with an amount of less than 150 ppm. Due to the low amount of conductive dopant in the ZnO target, the second transparent film 116 can be advantageously formed using high deposition rate processes such as DC sputtering or pulsed DC sputtering. The deposition rate of a DC sputtering process for a doped ZnO film can be as high as 6 nm/sec in the same deposition chamber. The deposition process may be performed in the same deposition chamber, where the first transparent film was deposited by RF sputtering, using a ZnO target including aluminum oxide (Al₂O₃) in the amount of less than 150 ppm. A preferred thickness range for the second transparent film may be in the range of 50-150 nm, preferably 100 nm. Use of DC sputtering allows the transparent layer 120 with a desired thickness to be formed in a cost effective and efficient manner. An exemplary thickness for the transparent layer may be in the range of 100-200 nm. Alternatively, the transparent layer 120 may be entirely made of the second transparent film 116, due to its very low conductive dopant concentration, without including the first transparent film 114.

The following deposition process exemplifies an embodiment of the invention. To deposit the transparent layer, first a 20 nm layer of intrinsic ZnO is deposited from an undoped ZnO target using RF sputtering with a power density of 2.1 W/cm² The deposition is performed in an Ar atmosphere with a pressure of 2 mT. The deposition rate for the first layer is 1.1 nm/sec. Subsequently, in the same deposition chamber, using a semi-intrinsic ZnO target (containing approximately 100 ppm of Al₂O₃,), a 70 nm layer is deposited by DC sputtering with a power density of 4.2 W/cm² in an Ar/2% O₂ atmosphere with a pressure of 2 mT. The deposition rate for the second layer under these conditions is 2.8 nm/sec. To compare the film properties of these layers, another sample is prepared by depositing a 90 nm intrinsic ZnO layer on a glass substrate using RF sputtering from an undoped ZnO target and the same conditions described above for the first sub-layer of the transparent layer. The table below compares the deposition times for the two different processes. As can be seen in the table, both transparent layers exhibit high electrical resistance necessary for high efficiency cells; however, the throughput of the bilayer process is significantly higher.

| | Total | |
|---|---|---|
| | Deposition | Resistivity |
| Layer | Time (sec) | (Ω · cm) |
| 90 nm intrinsic ZnO | 82 | >20 |
| 20 nm intrinsic ZnO/70 nm doped ZnO | 43 | >20 |

In another example, a transparent layer composed of an intrinsic ZnO sub-layer deposited by RF sputtering from an undoped ZnO target and a lightly doped ZnO sub-layer deposited by DC sputtering from a semi-intrinsic ZnO target can be formed in an inline process such as a roll to roll sputtering system with several deposition zones distributed across one or multiple deposition chambers. In the first deposition zone, the intrinsic layer is formed by RF sputtering using one or more undoped ZnO targets. In the second deposition zone, the semi-intrinsic transparent layer is deposited by DC sputtering using one or more semi-intrinsic ZnO targets. Finally, in a third deposition zone, the conductive transparent layer is deposited from one or more highly doped ZnO or ITO targets.

As shown in FIG. 2D, once the transparent layer 120 is formed using this two-step method, a transparent conductive layer 122 is deposited on the second transparent film 116 of the transparent layer 120. In this embodiment, the transparent conductive layer may preferably include an Al doped ZnO, although it may be an indium tin oxide (known as ITO) layer. The transparent conductive layer 122 preferably includes an Al concentration of 2-3% (wt. %) and it is sputter deposited from a conductive ZnO target doped with up to 2.0 to 3.0% Al₂O₃, by weight. FIG. 3 shows the solar cell structure after the deposition of the transparent layer 120 and the transparent conductive layer 122.

Consequently, with the first transparent film 114 adjacent the buffer layer 110, the transparent layer 120 provides a high quality interface needed by the buffer layer 110, and with the second transparent film 116 adjacent the transparent conductive layer 122, the transparent layer 120 effectively minimizes the diffusion of aluminum into the absorber layer via the buffer layer, thereby preventing any loss in solar cell efficiency.

Although the present invention is described with respect to certain preferred embodiments, modifications thereto will be apparent to those skilled in the art.

1. A method of depositing a transparent oxide material layer over an exposed surface of a solar cell buffer layer of a workpiece for manufacturing of solar cells, comprising:
depositing a transparent film using DC sputtering over the exposed surface of the solar cell buffer layer of the workpiece, the transparent film having a thickness range of 50-150 nm and being deposited from a semi-intrinsic zinc oxide target doped with a conductive dopant, wherein the transparent film has a conductive dopant concentration of less than 1000 ppm, wherein the transparent film thus forms the transparent oxide material layer.

2. The method according to claim 1 further including depositing another transparent film using RF sputtering on the exposed surface of the solar cell buffer layer, between the solar cell buffer layer and the transparent film, the another transparent film including undoped zinc oxide and having a thickness range of 10 to 40 nm, and wherein the transparent film and another second transparent film form the transparent oxide material layer

3. The method of claim 2 further comprising depositing a transparent conductive layer on the transparent oxide material layer, the transparent conductive layer including at least one of aluminum doped zinc oxide and indium tin oxide and having a thickness range of 25-500 nm.

4. The method of claim 3, wherein the conductive dopant in the transparent film is aluminum and the transparent film is sputter deposited from a semi-intrinsic ZnO ceramic target, and wherein Al₂O₃ concentration of the target is less than 1000 ppm.

5. The method of claim 3, wherein the DC sputtering process used to deposit the transparent film is pulsed DC sputtering.

6. The method of claim 3, wherein the transparent conductive layer is an aluminum doped zinc oxide layer and sputter deposited from a ZnO—Al₂O₃ ceramic target, and wherein Al₂O₃ amount of the target is in the range of 2-3% Al₂O₃ by weight.

7. The method of claim 1, wherein the DC sputtering process used to deposit the transparent film is pulsed DC sputtering.

8. A solar cell structure, comprising:
a IBIIIAVIA thin film absorber layer formed over a flexible substrate;
a buffer layer comprising CdS formed over the absorber layer;
a high electrical resistivity transparent layer formed on the buffer layer, the high electrical resistivity transparent layer comprising:
an intrinsic oxide film formed on the buffer layer, the intrinsic oxide film including undoped zinc oxide and having a thickness range of 10 to 40 nm, and
an intermediate oxide film formed on the intrinsic oxide film, the intermediate oxide film including semi-intrinsic zinc oxide doped with aluminum and having a thickness range of 50-150 nm, wherein the intermediate film has an aluminum concentration of less than 1000 ppm; and
a conductive oxide layer formed on the high electrical resistivity transparent layer, the conductive oxide layer including at least one of aluminum doped zinc oxide and indium tin oxide, and having a thickness range of 25-500 nm.

9. The solar cell structure of claim 8 further comprising a terminal structure, the terminal structure including conductive fingers and busbars formed over the conductive oxide layer.
